(19) United States
(12) Patent Application Publication
(10) Pub. No.: US 2010/0035420 A1
(43) Pub. Date: Feb. 11, 2010

(54) METHOD OF MANUFACTURING SEMICONDUCTOR DEVICE

(75) Inventors: Hideto Tamaso, Osaka-shi (JP); Kazuhiro Fujikawa, Osaka-shi (JP); Shin Harada, Osaka-shi (JP)

Correspondence Address: VENABLE LLP, P.O. BOX 34385, WASHINGTON, DC, 20043-9998, US

(73) Assignee: SUMITOMO ELECTRIC INDUSTRIES, LTD., Osaka-shi (JP)

(21) Appl. No.: 12/517,735

(22) PCT Filed: Nov. 29, 2007
(86) PCT No.: PCT/JP2007/073078

§ 371 Date: Jun. 4, 2009

(30) Foreign Application Priority Data
Dec. 13, 2006 (JP) 2006-336000

(51) Int. Cl. H01L 21/265

(52) U.S. Cl. 438/514; 257/E21.334

(57) ABSTRACT

A method of manufacturing a semiconductor device includes a first step of forming an ion implantation mask on a portion of a surface of a semiconductor; a second step of implanting ions of a first dopant into at least a portion of an exposed region of the surface of the semiconductor other than the region where the ion implantation mask is formed, to form a first dopant implantation region; a third step of, after forming the first dopant implantation region, removing a portion of the ion implantation mask to increase the exposed region of the surface of the semiconductor; and a fourth step of implanting ions of a second dopant into at least a portion of the increased exposed region of the surface of the semiconductor to form a second dopant implantation region.

### TECHNICAL FIELD

The present invention relates to a method of manufacturing a semiconductor device, and particularly to a method of manufacturing a semiconductor device that allows the semiconductor device to be reduced in size and also allows variations in characteristics of the semiconductor device to be reduced.

### BACKGROUND ART

An MOSFET (Metal-Oxide Semiconductor Field Effect Transistor; hereinafter also referred to as an “SiC-MOSFET”) which includes SiC (silicon carbide) and is a type of a semiconductor device is fabricated through the process roughly divided into selective ion implantation, activation annealing, gate oxide film formation, and electrode formation.

Referring to schematic cross-sectional views in FIGS. 20-30, an example of a conventional method of manufacturing an SiC-MOSFET will be hereinafter described.

First, as shown in FIG. 20, an n-type SiC film 202 is epitaxially grown on the surface of an SiC substrate 201. As shown in FIG. 21, an ion implantation mask 203 is then formed on the entire surface of SiC film 202.

Then, as shown in FIG. 22, a resist 204 having a predetermined opening 205 is formed on ion implantation mask 203 using the photolithography technique. As shown in FIG. 23, the portion of ion implantation mask 203 located under opening 205 is removed by etching to expose a portion of the surface of SiC film 202.

Then, as shown in FIG. 24, resist 204 is removed and ions of an n-type dopant such as phosphorus are ion-implanted into the exposed surface of SiC film 202 to thereby form an n-type dopant implantation region 206 on the surface of SiC film 202.

Then, as shown in FIG. 25, ion implantation mask 203 is entirely removed from the surface of SiC film 202. As shown in FIG. 26, ion implantation mask 203 is again formed on the entire surface of SiC film 202.

As shown in FIG. 27, resist 204 is partially formed on the surface of ion implantation mask 203 using the photolithography technique, in which resist 204 may be formed at the position displaced from the specified position depending on the accuracy of a photolithography apparatus, and the like.

Then, as shown in FIG. 28, a portion of ion implantation mask 203 in which resist 204 is not formed is removed by etching to thereby expose a portion of the surface of SiC film 202.

Then, as shown in FIG. 29, ions of a p-type dopant such as aluminum are ion-implanted into the exposed surface of SiC film 202 to thereby form a p-type dopant implantation region 207 on the surface of SiC film 202.

Ion implantation mask 203 and resist 204 are then removed and the activation annealing is carried out for restoring crystallinity of the wafer from which ion implantation mask 203 and resist 204 have been removed.

As shown in FIG. 30, a gate oxide film 208, a source electrode 209 and a drain electrode 211 are formed on the surface of SiC film 202, and a gate electrode 210 is formed on the surface of gate oxide film 208. Then, wiring is provided to each of source electrode 209, gate electrode 210 and drain electrode 211, and the wafer is divided into chips to thereby complete an SiC-MOSFET.

Non-Patent Document 1: Hiroyuki Matsunami (write and edit), “Semiconductor SiC Technology and Applications”, Nikkan Kogyo Shimbun-sha, March in 2003

### DISCLOSURE OF THE INVENTION

### Problems to be Solved by the Invention

Since a diffusion coefficient of a dopant is small in SiC, the n-type dopant and the p-type dopant each are introduced not by the diffusion method but by the ion implantation method.

However, as described above, the position where the resist to be used as an ion implantation mask for the implantation of the ions of the n-type dopant and the p-type dopant is formed varies depending on the accuracy of the photolithography apparatus, and the like. This causes a problem that variations occur in the relative positional relationship between the n-type dopant implantation region and the p-type dopant implantation region, with the result that variations occur in the gate length of the SiC-MOSFET to cause variations in characteristics of the SiC-MOSFET. Furthermore, it is also desired that the semiconductor device be further reduced in size.

An object of the present invention is to provide a method of manufacturing a semiconductor device that allows the semiconductor device to be reduced in size and also allows variations in characteristics of the semiconductor device to be reduced.

### Means for Solving the Problems

The present invention provides a method of manufacturing a semiconductor device including a first step of forming an ion implantation mask on a portion of the surface of a semiconductor; a second step of implanting ions of a first dopant into at least a portion of an exposed region of the surface of the semiconductor other than the region where the ion implantation mask is formed, to form a first dopant implantation region; a third step of, after forming the first dopant implantation region, removing a portion of the ion implantation mask to increase the exposed region of the surface of the semiconductor; and a fourth step of implanting ions of a second dopant into at least a portion of the increased exposed region of the surface of the semiconductor to form a second dopant implantation region.

According to the method of manufacturing the semiconductor device of the present invention, the ion implantation mask used for forming the first dopant implantation region can also be used for forming the second dopant implantation region, and the variation in the relative positional relationship between the first dopant implantation region and the second dopant implantation region can be reduced. This allows the semiconductor device to be reduced in size and also allows variations in characteristics of the semiconductor device to be reduced. Furthermore, according to the method of manufacturing the semiconductor device of the present invention, since only a single formation of the resist for patterning the ion implantation mask is required, the number of steps can also be reduced as compared to the conventional case.

Furthermore, in the method of manufacturing the semiconductor device of the present invention, it is preferable that the ion implantation mask includes at least one selected from a group consisting of tungsten, silicon, aluminum, nickel, and titanium. In this case, the ion implantation mask serves as a mask for the implantation of the ions of the first dopant and the second dopant, and can include an adhesion improving layer improving adhesion to the semiconductor surface and an etching stop layer allowing the etching on the semiconductor surface to be suppressed. The above-mentioned tungsten, silicon, aluminum, nickel, and titanium may each be contained in the ion implantation mask singly or may be contained in the ion implantation mask in the form of a compound.

Furthermore, in the method of manufacturing the semiconductor device of the present invention, the ion implantation mask may be formed of two or more layers. In the case where the ion implantation mask is formed of two or more layers, when a portion of the ion implantation mask is removed after the formation of the first dopant implantation region to increase the exposed region of the surface of the semiconductor, the ion implantation mask can be reduced in width while suppressing the reduction in thickness thereof. Consequently, the reliability of the ion implantation mask at the time of the implantation of the ions of the second dopant is improved.

Furthermore, in the method of manufacturing the semiconductor device of the present invention, the ion implantation mask may be formed of two layers including a first ion implantation mask and a second ion implantation mask formed on the first ion implantation mask. In this case, when a portion of the first ion implantation mask is removed after the formation of the first dopant implantation region to increase the exposed region of the surface of the semiconductor, the first ion implantation mask can be reduced in width while suppressing the reduction in thickness of the first ion implantation mask. Consequently, the reliability of the first ion implantation mask at the time of the implantation of the ions of the second dopant is improved.

Furthermore, in the above description, it is preferable that the first ion implantation mask contains tungsten as a main component and the second ion implantation mask contains silicon oxide as a main component. In this case, there is a significant tendency that the second ion implantation mask is resistant to etching during the etching of the first ion implantation mask and the first ion implantation mask is resistant to etching during the etching of the second ion implantation mask, and thus, the first ion implantation mask can be reduced in width while suppressing the reduction in thickness of the first ion implantation mask. Consequently, the reliability of the first ion implantation mask at the time of the implantation of the ions of the second dopant is improved.

Furthermore, in the method of manufacturing the semiconductor device of the present invention, the first step may be performed by stacking the first ion implantation mask and the second ion implantation mask in this order on the surface of the semiconductor to form the ion implantation mask, and subsequently, etching a portion of the ion implantation mask to thereby expose a portion of the surface of the semiconductor; the third step may be performed by, after forming the first dopant implantation region, etching the first ion implantation mask at least in its width direction; a step of removing the second ion implantation mask by etching may be included between the third step and the fourth step; and, a step of removing the first ion implantation mask by etching may be included after the fourth step. In this case, while reduction in size of the semiconductor device and reduction in variations in characteristics of the semiconductor device can be achieved, the number of steps can also be reduced as compared to the conventional case.

Furthermore, in the method of manufacturing the semiconductor device of the present invention, it is preferable that the selective ratio of the second ion implantation mask to the first ion implantation mask by an etching solution or etching gas for etching the second ion implantation mask is not less than 2. In this case, before implanting the ions of the second dopant, the etching of the second ion implantation mask can be suppressed and the first ion implantation mask can be etched in its width direction while suppressing the reduction in thickness of the first ion implantation mask. Consequently, the reliability of the first ion implantation mask at the time of the implantation of the ions of the second dopant is improved.

Furthermore, in the method of manufacturing the semiconductor device of the present invention, it is preferable that the etching in the first step and the etching in the third step each are performed by dry etching. In this case, in the first step in which the surface of the semiconductor is exposed, the etching tends to proceed in the thickness direction of each of the first ion implantation mask and the second ion implantation mask, and in the third step in which the exposed region of the surface of the semiconductor is increased, the etching in the width direction of each of the first ion implantation mask and the second ion implantation mask tends to be readily controlled. Accordingly, the first ion implantation mask and the second ion implantation mask can each be prevented from being needlessly etched during the etching of each of these ion implantation masks.

Furthermore, in the method of manufacturing the semiconductor device of the present invention, it is possible that the portion of the ion implantation mask is removed by etching in the third step and the ion implantation mask after the etching in the third step has a thickness serving as an implantation mask for the ions of the second dopant in the fourth step. In this case, the ion implantation mask serves as an implantation mask for the ions of the second dopant, which can prevent the second dopant implantation region from being formed in the portion where the second dopant implantation region is not required.

Furthermore, in the method of manufacturing the semiconductor device of the present invention, the ion implantation mask may contain tungsten as a main component. The ion implantation mask containing tungsten as a main component is preferable in that tungsten is a high density material and is highly capable of preventing the ion implantation, which allows the ion implantation mask to be formed thinner than in the case of other materials, with the result that the process tends to be simplified.

Furthermore, in the method of manufacturing the semiconductor device of the present invention, the first step may be performed by, after forming the ion implantation mask on the surface of the semiconductor, etching a portion of the ion implantation mask to thereby expose a portion of the surface of the semiconductor; the third step may be performed by, after forming the first dopant implantation region, etching the ion implantation mask at least in its width direction; and, a step of removing the ion implantation mask may be included after the fourth step. In this case, while reduction in size of the semiconductor device and reduction in variations in characteristics of the semiconductor device can be achieved, the number of steps can also be reduced as compared to the conventional case.

It is preferable that the etching in the first step and the etching in the third step each are performed by dry etching. In this case, in the first step in which the surface of the semiconductor is exposed, the etching tends to proceed in the thickness direction of the ion implantation mask, and in the third step in which the exposed region of the surface of the semiconductor is increased, the etching in the width direction of the ion implantation mask tends to be readily controlled. Accordingly, the ion implantation mask can be prevented from being needlessly etched during the etching of the ion implantation mask.

Furthermore, in the method of manufacturing the semiconductor device of the present invention, it is preferable that the semiconductor has a band gap energy of not less than 2.5 eV. This tends to allow the manufacture of the semiconductor device that withstands a high voltage, achieves loss low, and is excellent in heat resistance and environment resistance.

Furthermore, in the method of manufacturing the semiconductor device of the present invention, it is preferable that the semiconductor contains silicon carbide as a main component. In the semiconductor device made of silicon carbide, since the activation annealing temperature becomes high after the dopant implantation, the self-alignment method as in the conventional Si device cannot be used, and thus, the present invention can be particularly suitably used.

### EFFECTS OF THE INVENTION

According to the present invention, a method of manufacturing a semiconductor device can be provided that allows the semiconductor device to be reduced in size and also allows variations in characteristics of the semiconductor device to be reduced.

### BRIEF DESCRIPTION OF THE DRAWINGS

FIG. 1 is a schematic cross-sectional view showing a part of an example of a method of manufacturing a semiconductor device of the present invention.

FIG. 2 is a schematic cross-sectional view showing a part of the example of the method of manufacturing the semiconductor device of the present invention.

FIG. 3 is a schematic cross-sectional view showing a part of the example of the method of manufacturing the semiconductor device of the present invention.

FIG. 4 is a schematic cross-sectional view showing a part of the example of the method of manufacturing the semiconductor device of the present invention.

FIG. 5 is a schematic cross-sectional view showing a part of the example of the method of manufacturing the semiconductor device of the present invention.

FIG. 6 is a schematic cross-sectional view showing a part of the example of the method of manufacturing the semiconductor device of the present invention.

FIG. 7 is a schematic cross-sectional view showing a part of the example of the method of manufacturing the semiconductor device of the present invention.

FIG. 8 is a schematic cross-sectional view showing a part of the example of the method of manufacturing the semiconductor device of the present invention.

FIG. 9 is a schematic cross-sectional view showing a part of the example of the method of manufacturing the semiconductor device of the present invention.

FIG. 10 is a schematic cross-sectional view showing a part of the example of the method of manufacturing the semiconductor device of the present invention.

FIG. 11 is a schematic cross-sectional view showing a part of another example of the method of manufacturing the semiconductor device of the present invention.

FIG. 12 is a schematic cross-sectional view showing a part of another example of the method of manufacturing the semiconductor device of the present invention.

FIG. 13 is a schematic cross-sectional view showing a part of another example of the method of manufacturing the semiconductor device of the present invention.

FIG. 14 is a schematic cross-sectional view showing a part of another example of the method of manufacturing the semiconductor device of the present invention.

FIG. 15 is a schematic cross-sectional view showing a part of another example of the method of manufacturing the semiconductor device of the present invention.

FIG. 16 is a schematic cross-sectional view showing a part of another example of the method of manufacturing the semiconductor device of the present invention.

FIG. 17 is a schematic cross-sectional view showing a part of another example of the method of manufacturing the semiconductor device of the present invention.

FIG. 18 is a schematic cross-sectional view showing a part of another example of the method of manufacturing the semiconductor device of the present invention.

FIG. 19 is a schematic cross-sectional view showing a part of another example of the method of manufacturing the semiconductor device of the present invention.

FIG. 20 is a schematic cross-sectional view showing a part of an example of a method of manufacturing a conventional SiC-MOSFET.

FIG. 21 is a schematic cross-sectional view showing a part of the example of the method of manufacturing the conventional SiC-MOSFET.

FIG. 22 is a schematic cross-sectional view showing a part of the example of the method of manufacturing the conventional SiC-MOSFET.

FIG. 23 is a schematic cross-sectional view showing a part of the example of the method of manufacturing the conventional SiC-MOSFET.

FIG. 24 is a schematic cross-sectional view showing a part of the example of the method of manufacturing the conventional SiC-MOSFET.

FIG. 25 is a schematic cross-sectional view showing a part of the example of the method of manufacturing the conventional SiC-MOSFET.

FIG. 26 is a schematic cross-sectional view showing a part of the example of the method of manufacturing the conventional SiC-MOSFET.

FIG. 27 is a schematic cross-sectional view showing a part of the example of the method of manufacturing the conventional SiC-MOSFET.

FIG. 28 is a schematic cross-sectional view showing a part of the example of the method of manufacturing the conventional SiC-MOSFET.

FIG. 29 is a schematic cross-sectional view showing a part of the example of the method of manufacturing the conventional SiC-MOSFET.

FIG. 30 is a schematic cross-sectional view showing a part of the example of the method of manufacturing the conventional SiC-MOSFET.

### DESCRIPTION OF THE REFERENCE SIGNS

101, 201 SiC substrate, 102, 202 SiC film, 103, 203 ion implantation mask, 103a first ion implantation mask, 103b second ion implantation mask, 104, 204 resist, 105, 205 opening, 106, 206 n-type dopant implantation region, 107, 207 p-type dopant implantation region, 108, 208 gate oxide film, 109, 209 source electrode, 110, 210 gate electrode, 111, 211 drain electrode.

### BEST MODES FOR CARRYING OUT THE INVENTION

The embodiments of the present invention will be hereinafter described. In the accompanying drawings of the present invention, the same or corresponding components are designated by the same reference characters.

### First Embodiment

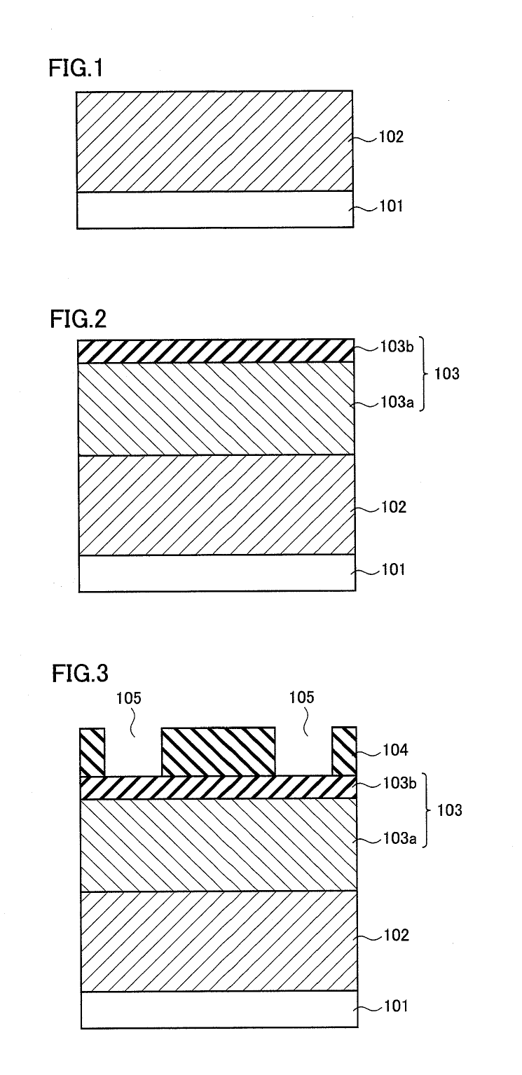

Referring to the schematic cross-sectional views in FIGS. 1-10, an example of the method of manufacturing the semiconductor device of the present invention will be hereinafter described.

First, as shown in FIG. 1, an n-type SiC film 102 is epitaxially grown on the surface of an SiC substrate 101 to form a wafer. Then, as shown in FIG. 2, a first ion implantation mask 103a made of tungsten is formed on the entire surface of SiC film 102, and, on the surface of first ion implantation mask 103a, a second ion implantation mask 103b made of silicon oxide is formed, with the result that an ion implantation mask 103 made of a stacked body including first ion implantation mask 103a and second ion implantation mask 103b is formed.

First ion implantation mask 103a made of tungsten and second ion implantation mask 103b made of silicon oxide each can be formed by, for example, the sputtering method, the CVD (Chemical Vapor Deposition) method, or the like.

Furthermore, it is preferable that first ion implantation mask 103a made of tungsten is formed to have a thickness of not more than 2 μm, and more preferably a thickness of not more than 1 μm. It is also preferable that second ion implantation mask 103b made of silicon oxide is formed to have a thickness of not more than 0.5 μm, and more preferably a thickness of not more than 0.3 μm.

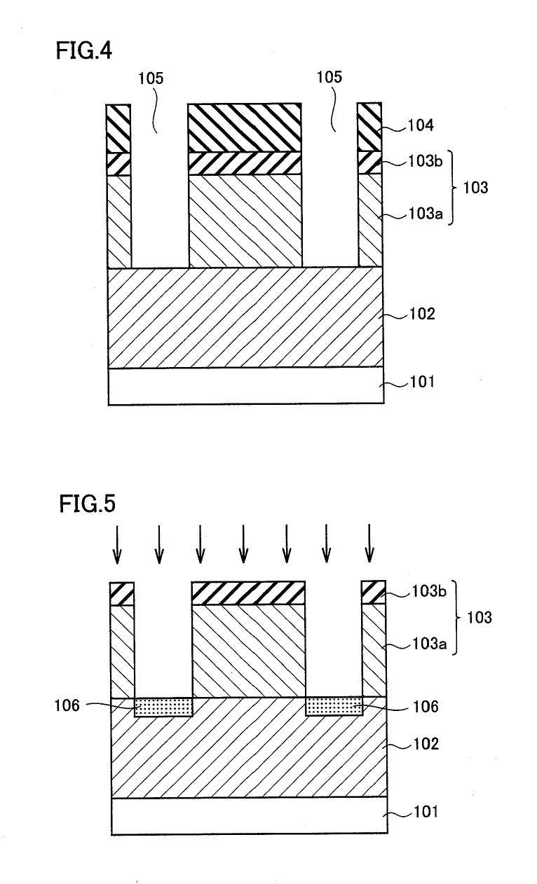

As shown in FIG. 3, a resist 104 having a predetermined opening 105 is then formed on second ion implantation mask 103b using, for example, the photolithography technique. Then, as shown in FIG. 4, a portion of each of first ion implantation mask 103a and second ion implantation mask 103b located under opening 105 is removed in the thickness direction by etching, to expose a portion of the surface of SiC film 102.

As shown in FIG. 5, resist 104 is then removed and ions of an n-type dopant such as phosphorus are ion-implanted into the exposed surface of SiC film 102 to thereby form an n-type dopant implantation region 106 on the surface of SiC film 102.

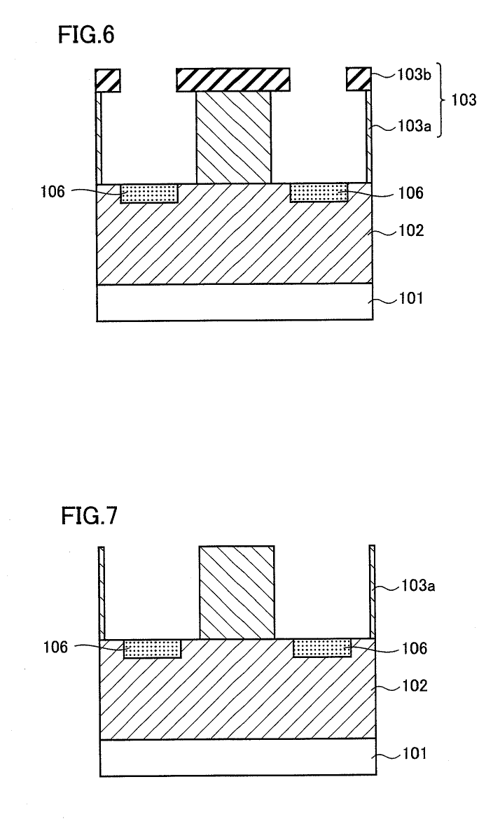

As shown in FIG. 6, first ion implantation mask 103a is etched in its width direction to decrease the width of first ion implantation mask 103a. This causes exposure of the region of the surface of SiC film 102 other than the region where n-type dopant implantation region 106 is formed, to increase the exposed region of the surface of SiC film 102.

The material used as an etching solution or etching gas for etching first ion implantation mask 103a has a property in which first ion implantation mask 103a is etched more readily than in the case of second ion implantation mask 103b.

Then, as shown in FIG. 7, second ion implantation mask 103b on first ion implantation mask 103a is removed by etching. The material used as the etching solution or etching gas for etching second ion implantation mask 103b has a property in which second ion implantation mask 103b is etched more readily than in the case of first ion implantation mask 103a.

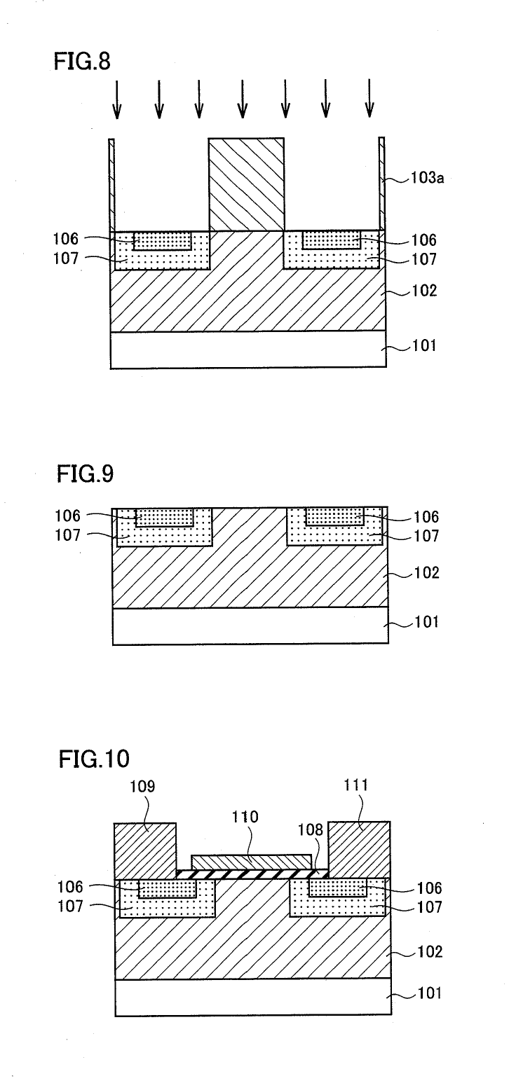

As shown in FIG. 8, ions of a p-type dopant such as aluminum are ion-implanted into the thus increased exposed region of the surface of SiC film 102, to thereby form a p-type dopant implantation region 107 on the surface of SiC film 102.

As shown in FIG. 9, first ion implantation mask 103a is removed. Then, the activation annealing is carried out for restoring crystallinity of the wafer from which first ion implantation mask 103a has been removed and also activating the ions of the ion-implanted n-type dopant and p-type dopant.

As shown in FIG. 10, after a gate oxide film 108, a source electrode 109 and a drain electrode 111 are formed on the surface of SiC film 102 and a gate electrode 110 is formed on the surface of gate oxide film 108, the wafer is divided into chips to thereby complete an SiC-MOSFET.

Thus, in the present embodiment, the ion implantation mask used for forming the n-type dopant implantation region can also be used for forming the p-type dopant implantation region. This eliminates the need to separately form the ion implantation mask for forming the n-type dopant implantation region and the ion implantation mask for forming the p-type dopant implantation region as in the conventional case.

Therefore, as compared to the conventional case, it is possible to reduce the variation in the relative positional relationship between the n-type dopant implantation region and the p-type dopant implantation region and to shorten the gate length, which leads to reduction in size of the semiconductor device. The reduction in the variation also allows variations in characteristics of the semiconductor device to be reduced.

Furthermore, since only a single formation of the resist for patterning the ion implantation mask is required, the number of steps can also be reduced as compared to the conventional case.

Ion implantation mask 103 may include the layer made of, for example, titanium, nickel, silicon oxide, or silicon nitride between first ion implantation mask 103a made of tungsten and the surface of SiC film 102. This layer is provided because it may improve the adhesion between ion implantation mask 103 and SiC film 102 and may also serve as an etching stop layer of the surface of SiC film 102. This layer can be formed, for example, to have a thickness of not more than 100 nm.

In the above description, although tungsten is used for first ion implantation mask 103a and silicon oxide is used for second ion implantation mask 103b, it goes without saying that the present invention is not limited thereto. For example, a silicon compound such as silicon oxide, silicon nitride or silicon oxynitride can be used for first ion implantation mask 103a, and metal such as aluminum or titanium can be used for second ion implantation mask 103b.

In other words, the material used for first ion implantation mask 103a may have a property that is more resistant to etching by the etching solution or etching gas for etching second ion implantation mask 103b than in the case of second ion implantation mask 103b. The material used for second ion implantation mask 103b may have a property that is more resistant to etching by the etching solution or etching gas for etching first ion implantation mask 103a than in the case of first ion implantation mask 103a.

Particularly, it is preferable to use tungsten for first ion implantation mask 103a and to use silicon oxide for second ion implantation mask 103b. In this case, second ion implantation mask 103b tends to be more resistant to etching during the etching of first ion implantation mask 103a, and first ion implantation mask 103a tends to be more resistant to etching during the etching of second ion implantation mask 103b. Thus, first ion implantation mask 103a can be reduced in width while suppressing the reduction in thickness of first ion implantation mask 103a. Therefore, the reliability of first ion implantation mask 103a at the time of the implantation of the ions of the second dopant can be improved.

It is to be noted that, in the present invention, ion implantation mask 103 is not limited to the above-described two-layer configuration, but may be one layer or may be three or more layers.

Furthermore, it is preferable that the selective ratio of second ion implantation mask 103b to first ion implantation mask 103a by the etching solution or etching gas for etching second ion implantation mask 103b is not less than 2. In this case, before implanting the ions of the p-type dopant, the etching of second ion implantation mask 103b can be suppressed and first ion implantation mask 103a can be etched in its width direction while suppressing the reduction in thickness of first ion implantation mask 103a. Consequently, the reliability of first ion implantation mask 103a at the time of the implantation of the ions of the p-type dopant is improved.

The above-mentioned selective ratio can be calculated by etching first ion implantation mask 103a and second ion implantation mask 103b by the etching solution or etching gas on the same conditions and obtaining the ratio between the etching rate of first ion implantation mask 103a and the etching rate of second ion implantation mask 103b (the etching rate of first ion implantation mask 103a/the etching rate of second ion implantation mask 103b).

In the above description, it is preferable that the etching of each of first ion implantation mask 103a and second ion implantation mask 103b in the thickness direction shown in FIG. 4 is carried out by dry etching using etching gas. Although the etching of first ion implantation mask 103a in its width direction shown in FIG. 6 may also be carried out by wet etching using etching solution, it is preferable that the etching is carried out by dry etching using etching gas.

In the case of the dry etching using etching gas, a bias voltage is generally applied to SiC substrate 101 and the etching gas proceeds with a certain directivity in the direction of SiC substrate 101. Accordingly, the etching tends to proceed in the thickness direction of each of first ion implantation mask 103a and second ion implantation mask 103b as compared to the case of the wet etching. Furthermore, in the case of the wet etching using etching solution, the isotropic etching tends to proceed, and therefore, the etching tends to proceed in the width direction of first ion implantation mask 103a as compared to the case of the dry etching. However, for the purpose of facilitating the etching control, it is preferable to etch first ion implantation mask 103a in its width direction by dry etching using etching gas.

In the above description, SiC is used as a semiconductor, but it goes without saying that a semiconductor other than SiC may be used. In the present invention, for example, gallium nitride, diamond, zinc oxide, aluminum nitride, or the like may be used as a semiconductor.

Particularly, in the present invention, it is preferable to use a semiconductor having a band gap energy of not less than 2.5 eV. This tends to allow the manufacture of the semiconductor device that withstands a high voltage, achieves low loss, and is excellent in heat resistance and environment resistance.

In the above description, although the case where an SiC-MOSFET is manufactured as a semiconductor device has been described, it goes without saying that, in the present invention, a semiconductor device other than the SiC-MOSFET may be manufactured using a semiconductor other than SiC.

Furthermore, it goes without saying that, in the present invention, the above-described p-type conductivity and n-type conductivity may be replaced with each other.

### Second Embodiment

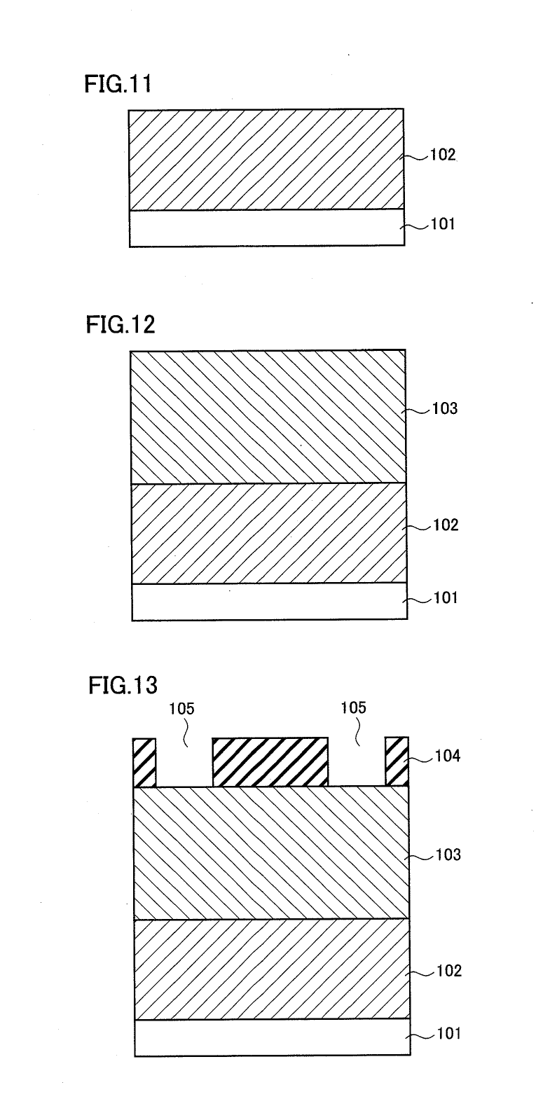

Referring to the schematic cross-sectional views in FIGS. 11-19, an example of the method of manufacturing the semiconductor device of the present invention will be hereinafter described.

First, as shown in FIG. 11, n-type SiC film 102 is epitaxially grown on the surface of SiC substrate 101 to form a wafer. Then, as shown in FIG. 12, ion implantation mask 103 made of tungsten is formed on the entire surface of SiC film 102.

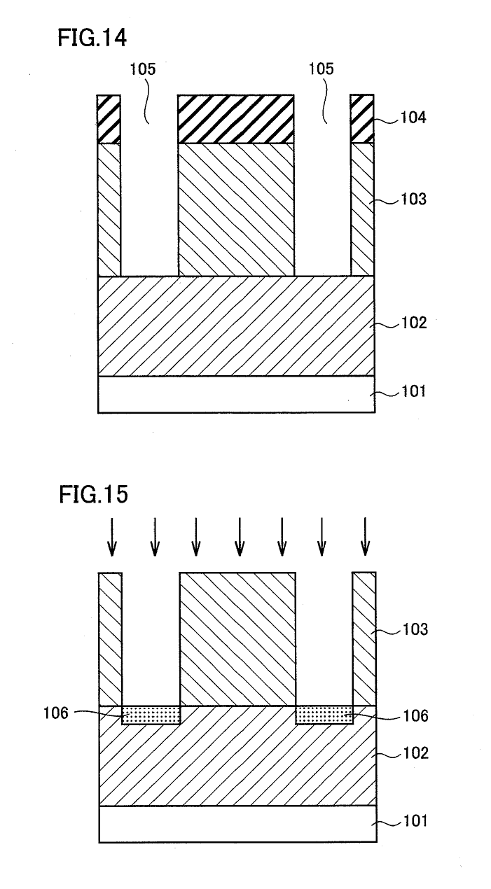

As shown in FIG. 13, resist 104 having predetermined opening 105 is then formed on the surface of ion implantation mask 103 using, for example, the photolithography technique. Then, as shown in FIG. 14, a portion of implantation mask 103 located under opening 105 is removed by etching to expose a portion of the surface of SiC film 102.

Then, as shown in FIG. 15, resist 104 is removed and ions of an n-type dopant such as phosphorus are ion-implanted into the exposed surface of SiC film 102 to thereby form n-type dopant implantation region 106 on the surface of SiC film 102.

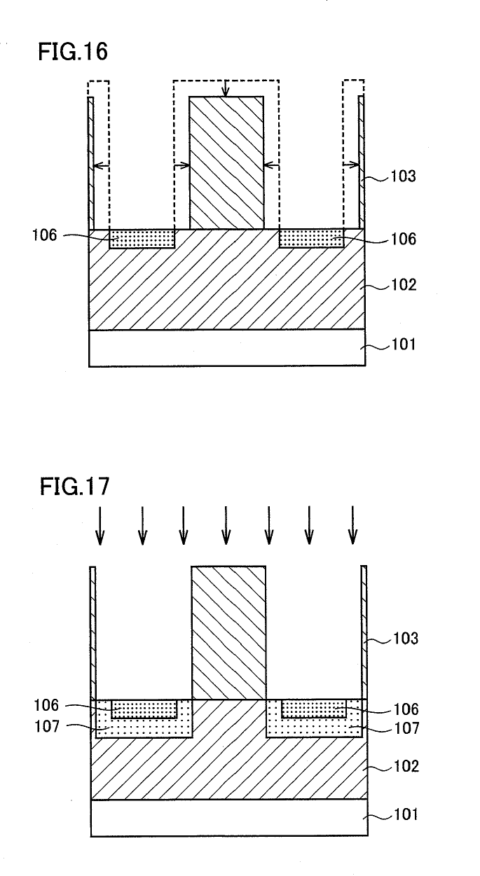

Then, as shown in FIG. 16, ion implantation mask 103 is subjected to isotropic etching and is removed in its width direction to reduce the width of ion implantation mask 103. This causes exposure of the region of the surface of SiC film 102 other than the region where n-type dopant implantation region 106 is formed, to increase the exposed region of the surface of SiC film 102.

In the present embodiment, the above-described isotropic etching causes ion implantation mask 103 to be entirely etched, with the result that not only the width but also the height of ion implantation mask 103 is reduced.

Then, as shown in FIG. 17, the ions of the p-type dopant such as aluminum are ion-implanted into the thus increased exposed region of the surface of SiC film 102, to thereby form p-type dopant implantation region 107 on the surface of SiC film 102.

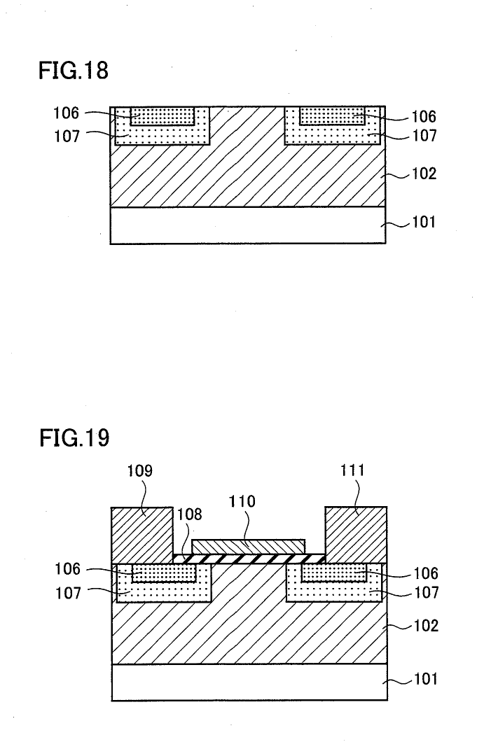

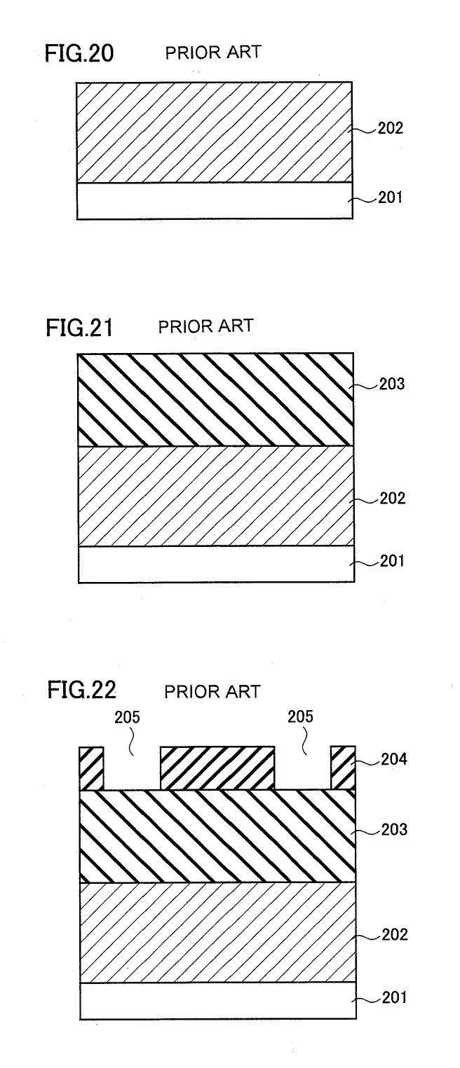

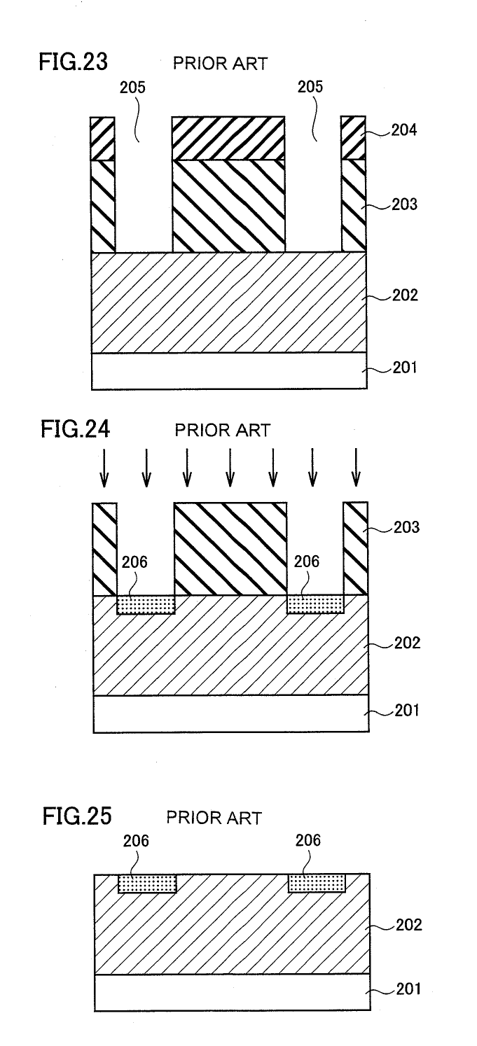

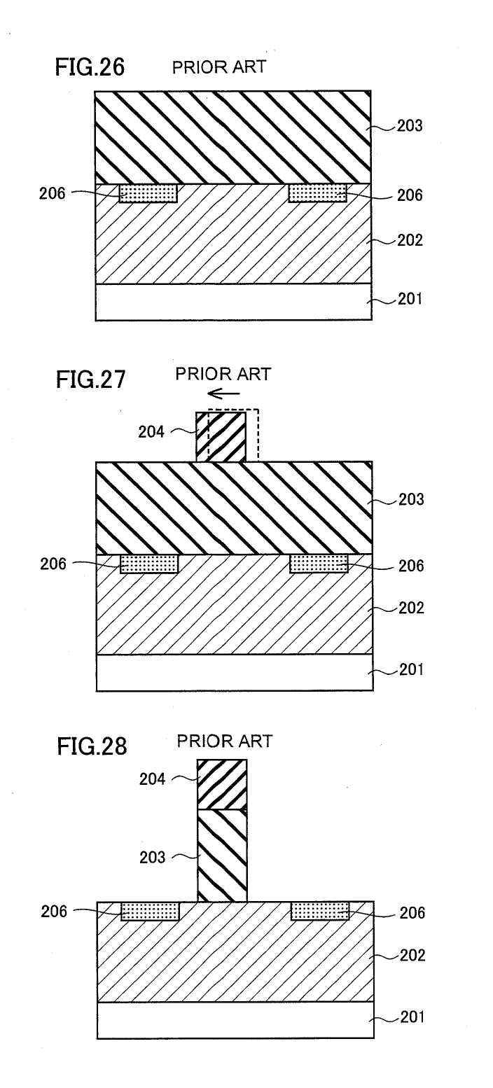

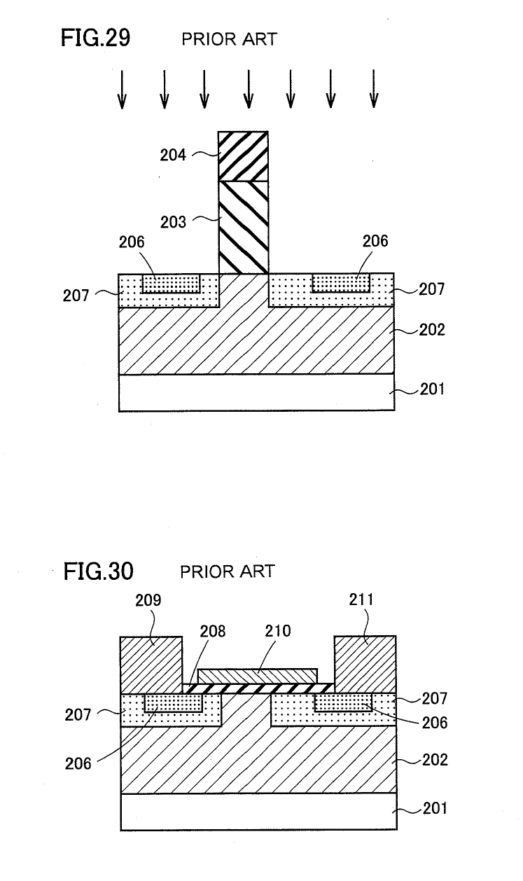

As shown in FIG. 18, ion implantation mask 103 is removed. Then, the activation annealing is carried out for restoring crystallinity of the wafer from which ion implantation mask 103 has been removed.

As shown in FIG. 19, after gate oxide film 108, source electrode 109 and drain electrode 111 are formed on the surface of SiC film 102 and gate electrode 110 is formed on the surface of gate oxide film 108, the wafer is divided into chips to thereby complete an SiC-MOSFET.

Thus, in the present embodiment, the ion implantation mask used for forming the n-type dopant implantation region can also be used for forming the p-type dopant implantation region. This eliminates the need to separately form the ion implantation mask for forming the n-type dopant implantation region and the ion implantation mask for forming the p-type dopant implantation region.

Therefore, as compared to the conventional case, it is possible to reduce the variation in the relative positional relationship between the n-type dopant implantation region and the p-type dopant implantation region and to shorten the gate length, which leads to reduction in size of the semiconductor device. The reduction in the variation also allows variations in characteristics of the semiconductor device to be reduced.

Furthermore, since only a single formation of the resist for patterning ion implantation mask 103 is required, the number of steps can also be reduced as compared to the conventional case.

In the present embodiment, although tungsten is used for ion implantation mask 103, it goes without saying that the present invention is not limited thereto.

Furthermore, in the above description, it is preferable that ion implantation mask 103 after the etching shown in FIG. 16 has a thickness that serves as an ion implantation mask in the subsequent ion implantation of the ions of the p-type dopant. This is because, when ion implantation mask 103 after the etching shown in FIG. 16 does not serve as an ion implantation mask in the ion implantation described below, p-type dopant implantation region 107 is formed in the area where it is not required. The thickness serving as an ion implantation mask means a thickness that allows 99.9% or more of the ion-implanted ions to be prevented from being implanted.

For example, in the case where ion implantation mask 103 is reduced in width by x from either side thereof by the etching shown in FIG. 16, ion implantation mask 103 may be reduced in thickness by x or more. In this case, it is sufficient that the thickness of ion implantation mask 103 after reduction by x or more is equal to or greater than the thickness serving as an ion implantation mask.

Furthermore, in the above description, it is preferable that the etching of ion implantation mask 103 in the thickness direction shown in FIG. 14 is carried out by dry etching using etching gas. Furthermore, although the etching of ion implantation mask 103 shown in FIG. 16 may also be carried out by wet etching using etching solution, it is preferable that the etching is carried out by dry etching using etching gas.

As described above, in the case of the dry etching using etching gas, the etching gas proceeds with a certain directivity in the direction of SiC substrate 101. Accordingly, the etching tends to proceed in the thickness direction of ion implantation mask 103 as compared to the case of the wet etching. Furthermore, in the case of the wet etching using etching solution, the isotropic etching tends to proceed, and therefore, the etching tends to proceed in the width direction of ion implantation mask 103 as compared to the case of the dry etching. However, for the purpose of facilitating the etching control, it is preferable to etch ion implantation mask 103 in its width direction by dry etching using etching gas.

It is to be noted that other descriptions in the present embodiment are the same as those in the first embodiment.

### EXAMPLE

### Example 1

A wafer having an n-type SiC film epitaxially grown on the surface of an SiC substrate was first prepared, in which the epitaxially grown n-type SiC film had a film thickness of 10 μm and the n-type dopant had a concentration of 1×10¹⁵ cm⁻³.

Then, a first ion implantation mask made of tungsten was formed on the entire surface of the SiC film by the sputtering method, and a second ion implantation mask made of silicon oxide was formed on the first ion implantation mask by the sputtering method, in which the first ion implantation mask had a thickness of 800 nm and the second ion implantation mask had a thickness of 100 nm.

Then, the photolithography technique was used to form on the second ion implantation mask a resist patterned so as to have an opening in the portion of the n-type dopant implantation region to be formed.

Then, the portion of the second ion implantation mask exposed from the opening of the resist was etched by CF₄ gas for removal. The portion of the first ion implantation mask exposed from the second ion implantation mask removed as described above was etched by SF₆ gas, to expose the surface of the SiC film located under the opening of the above-described resist.

CF₄ gas was an etching gas by which the second ion implantation mask made of silicon oxide was etched more than in the case of the first ion implantation mask made of tungsten. Furthermore, SF₆ gas was an etching gas by which the first ion implantation mask made of tungsten was etched more than in the case of the second ion implantation mask made of silicon oxide.

The resist was then removed and phosphorus ions were ion-implanted into the exposed surface of the SiC film to thereby form an n-type dopant implantation region in a portion of the surface of the SiC film, in which the n-type dopant implantation region was formed by implanting phosphorus ions on the condition that the dose amount was 1×10¹⁵ cm⁻².

Immersion in the etching solution made of the mixed solution of ammonia aqueous solution and hydrogen peroxide solution for 2 minutes caused the side surface of the first ion implantation mask made of tungsten to be etched in its width direction by a thickness of 0.5 μm. This causes exposure of the region of the surface of the SiC film other than the region where the n-type dopant implantation region was formed.

The etching solution made of the mixed solution of ammonia aqueous solution and hydrogen peroxide solution was an etching solution by which the first ion implantation mask made of tungsten was etched more than in the case of the second ion implantation mask made of silicon oxide.

Then, the second ion implantation mask made of silicon oxide was entirely removed by the etching using buffered hydrofluoric acid. Buffered hydrofluoric acid was an etching solution by which the second ion implantation mask made of silicon oxide was etched more than in the case of the first ion implantation mask made of tungsten.

Aluminum ions were implanted into the exposed surface of the SiC film to thereby form a p-type dopant implantation region on the surface of the SiC film, in which the p-type dopant implantation region was formed by implanting aluminum ions on the condition that the dose amount was 1×10¹⁴ cm⁻².

Then, the first ion implantation mask made of tungsten was entirely removed by the etching using the etching solution made of the mixed solution of ammonia aqueous solution and hydrogen peroxide solution. The wafer was then heated to 1700° C. to be subjected to activation annealing for restoring crystallinity, and to activate the ion-implanted dopant.

Then, a gate oxide film made of silicon oxide was formed to have a film thickness of 100 nm on the surface of the SiC film by the thermal oxidation method.

After a source electrode and a drain electrode were formed and a gate electrode was formed on the surface of the gate oxide film, the wafer was divided into chips to complete an SiC-MOSFET.

### Example 2

A wafer having an n-type SiC film epitaxially grown on the surface of an SiC substrate was first prepared, in which the epitaxially grown n-type SiC film had a film thickness of 10 μm and the n-type dopant had a concentration of 1×10¹⁵ cm⁻³.

Then, the ion implantation mask made of tungsten was formed to have a film thickness of 1600 nm on the entire surface of the SiC film by the sputtering method.

Then, the photolithography technique was used to form on the above-described ion implantation mask a resist patterned so as to have an opening in the portion of the n-type dopant implantation region to be formed.

Then, the portion of the ion implantation mask made of tungsten exposed from the opening of the resist was etched by SF₆ gas, to expose the surface of the SiC film located under the opening of the above-described resist.

The resist was then removed and phosphorus ions were ion-implanted into the exposed surface of the SiC film to thereby form an n-type dopant implantation region in a portion of the surface of the SiC film, in which the n-type dopant implantation region was formed by implanting phosphorus ions on the condition that the dose amount was 1×10¹⁵ cm⁻².

Then, the ion implantation mask made of tungsten was subjected to dry etching using SF₆ gas, in which the conditions of the dry etching were assumed to be close to those of the isotropic etching. After the dry etching, the width of the ion implantation mask made of tungsten was reduced by 800 nm and the thickness of the ion implantation mask was reduced by 400 nm. Therefore, the ion implantation mask after the above-described dry etching had a thickness of 1200 nm.

Aluminum ions were implanted into the exposed surface of the SiC film to thereby form a p-type dopant implantation region on the surface of the SiC film, in which the p-type dopant implantation region was formed by implanting aluminum ions on the condition that the dose amount was 1×10¹⁴ cm⁻².

The thickness serving as an ion implantation mask in the ion implantation of aluminum ions was 800 nm. Therefore, it was confirmed that the ion implantation mask after the above-described dry etching had a sufficient thickness serving as an ion implantation mask in the ion implantation of aluminum ions.

Then, the ion implantation mask made of tungsten was entirely removed by the etching using the etching solution made of the mixed solution of ammonia aqueous solution and hydrogen peroxide solution. The wafer was then heated to 1700° C. to be subjected to activation annealing for restoring crystallinity, and to activate the ion-implanted dopant.

Then, a gate oxide film made of silicon oxide was formed to have a film thickness of 100 nm on the surface of the SiC film by the thermal oxidation method.

After a source electrode and a drain electrode were formed and a gate electrode was formed on the surface of the gate oxide film, the wafer was divided into chips to complete an SiC-MOSFET.

It should be understood that the embodiments and the examples disclosed herein are illustrative and non-restrictive in every respect. The scope of the present invention is defined by the terms of the claims, rather than the description above, and is intended to include any modifications within the scope and meaning equivalent to the terms of the claims.

### INDUSTRIAL APPLICABILITY

According to the present invention, a method of manufacturing a semiconductor device can be provided that allows the semiconductor device to be reduced in size and also allows variations in characteristics of the semiconductor device to be reduced.

1. A method of manufacturing a semiconductor device, comprising:
a first step of forming an ion implantation mask on a portion of a surface of a semiconductor;
a second step of implanting ions of a first dopant into at least a portion of an exposed region of the surface of said semiconductor other than a region where said ion implantation mask is formed, to form a first dopant implantation region;
a third step of, after forming said first dopant implantation region, removing a portion of said ion implantation mask to increase the exposed region of the surface of said semiconductor; and
a fourth step of implanting ions of a second dopant into at least a portion of said increased exposed region of the surface of said semiconductor to form a second dopant implantation region.

2. The method of manufacturing the semiconductor device according to claim 1, wherein said ion implantation mask includes at least one selected from a group consisting of tungsten, silicon, aluminum, nickel, and titanium.

3. The method of manufacturing the semiconductor device according to claim 1, wherein said ion implantation mask is formed of two or more layers.

4. The method of manufacturing the semiconductor device according to claim 3, wherein said ion implantation mask is formed of two layers including a first ion implantation mask and a second ion implantation mask formed on said first ion implantation mask.

5. The method of manufacturing the semiconductor device according to claim 4, wherein said first ion implantation mask contains tungsten as a main component and said second ion implantation mask contains silicon oxide as a main component.

6. The method of manufacturing the semiconductor device according to claim 4, wherein
said first step is performed by stacking said first ion implantation mask and said second ion implantation mask in this order on the surface of said semiconductor to form said ion implantation mask, and subsequently, etching a portion of said ion implantation mask to thereby expose a portion of the surface of said semiconductor,
said third step is performed by, after forming said first dopant implantation region, etching said first ion implantation mask at least in its width direction,
a step of removing said second ion implantation mask by etching is included between said third step and said fourth step, and,
a step of removing said first ion implantation mask by etching is included after said fourth step.

7. The method of manufacturing the semiconductor device according to claim 6, wherein a selective ratio of said second ion implantation mask to said first ion implantation mask by an etching solution or etching gas for etching said second ion implantation mask is not less than 2.

8. The method of manufacturing the semiconductor device according to claim 6, wherein the etching in said first step and the etching in said third step each are performed by dry etching.

9. The method of manufacturing the semiconductor device according to claim 1, wherein the portion of said ion implantation mask is removed by etching in said third step and said ion implantation mask after the etching in said third step has a thickness serving as an implantation mask for the ions of said second dopant in said fourth step.

10. The method of manufacturing the semiconductor device according to claim 9, wherein said ion implantation mask contains tungsten as a main component.

11. The method of manufacturing the semiconductor device according to claim 9, wherein
said first step is performed by, after forming said ion implantation mask on the surface of said semiconductor, etching a portion of said ion implantation mask to thereby expose a portion of the surface of said semiconductor,
said third step is performed by, after forming said first dopant implantation region, etching said ion implantation mask at least in its width direction, and,
a step of removing said ion implantation mask is included after said fourth step.

12. The method of manufacturing the semiconductor device according to claim 11, wherein the etching in said first step and the etching in said third step each are performed by dry etching.

13. The method of manufacturing the semiconductor device according to claim 1, wherein said semiconductor has a band gap energy of not less than 2.5 eV.

14. The method of manufacturing the semiconductor device according to claim 13, wherein said semiconductor contains silicon carbide as a main component.
